(19) United States
(12) Patent Application Publication
(10) Pub. No.: US 2026/0043671 A1
(43) Pub. Date: Feb. 12, 2026

(54) SYSTEM AND METHOD FOR GENERATING 3D MAP

(71) Applicant: HYUNDAI MOBIS CO., LTD., Seoul (KR)

(72) Inventors: Tae Hyeon JEONG, Yongin-si (KR); Jae Jun SONG, Yongin-si (KR); Jae Woo JANG, Yongin-si (KR); So Yeon KIM, Yongin-si (KR)

(73) Assignee: HYUNDAI MOBIS CO., LTD., Seoul (KR)

(21) Appl. No.: 19/067,157

(22) Filed: Feb. 28, 2025

(30) Foreign Application Priority Data
Aug. 8, 2024 (KR) 10-2024-0106287

(51) Int. Cl. G01C 21/00

(52) U.S. Cl. CPC G01C 21/383; G01C 21/3859

(57) ABSTRACT

The present disclosure relates to a system and a method for generating a three-dimensional (3D) map. The method for generating the (3D) map includes obtaining a two-dimensional (2D) map of a space by utilizing one of a floor plan and robot data based on a user's input, generating a robust 2D map from the 2D map via a post-processing modification process, and generating the 3D map from the robust 2D map.

### CROSS-REFERENCE TO RELATED APPLICATIONS

Pursuant to 35 U.S.C. § 119(a), this application claims the benefit of earlier filing dates and right of priority to Korean Application No. 10-2024-0106287, filed on Aug. 8, 2024, the contents of which are hereby incorporated by reference herein in their entirety.

### TECHNICAL FIELD

Following description relates to a system and a method for generating a three-dimensional (3D) map that generate the 3D map from a two-dimensional (2D) map for robot simulation utilization.

### BACKGROUND

In general, in an environment with a great area size and many moving objects such as a factory, three-dimensional (3D) simulation and verification of interference/collision in a virtual environment similar to the actual environment are required.

However, contrary to reality with the needs, significant time and labor are required currently as an engineer or the like remains on-site for a long time for the factory simulation and performs stabilization via several adjustment processes.

In addition, cost is high because a high-performance device or an expensive sensor is required for 3D restoration of an actual space.

Therefore, it is necessary to implement a 3D environment using only a design drawing or a map generated by a robot.

### SUMMARY

The present disclosure is intended to solve the above-described problems, and according to embodiments, the present disclosure is intended to provide a system and a method for generating a three-dimensional (3D) map that may generate the 3D map using a design drawing or robot data.

In addition, according to embodiments, the present disclosure is intended to provide a system and a method for generating a 3D map that may construct a 3D environment based on the generated 3D map and perform simulation.

The problem to be solved by the present disclosure is not limited to the above, and other problems not mentioned will be clearly understood by those skilled in the art to which the present disclosure belongs from the description below.

A method for generating a three-dimensional (3D) map according to embodiments to solve the above-described problems as described above includes obtaining a two-dimensional (2D) map of a space by utilizing one of a floor plan and robot data based on a user's input, generating a robust 2D map from the 2D map via a post-processing modification process, and generating the 3D map from the robust 2D map.

According to embodiments, the post-processing modification process may include at least one of a modification process based on selective use of a filter and a modification process based on manipulation of a user interface (UI).

According to embodiments, the generating of the 3D map may include generating mesh-based 3D map data from the robust 2D map, optimizing the generated 3D map data, and generating the 3D map based on the optimized 3D map data.

According to embodiments, the generating of the 3D map may include generating the 3D map from the robust 2D map using a filter.

According to embodiments, the method may further include determining whether to execute the post-processing modification process based on a degree of match between the generated 3D map and an actual map.

According to embodiments, the method may further include simulating a movement of a moving object using the generated 3D map, and the simulating of the movement of the moving object may include determining whether to modify the 3D map based on data obtained from the movement of the moving object.

According to embodiments, the method may further include reflecting actual environment data obtained based on the movement of the moving object into the generated 3D map.

A system for generating a three-dimensional (3D) map according to embodiments to solve the above-described problems as described above includes a two-dimensional (2D) map generator that obtains a 2D map of a space by utilizing one of a floor plan and robot data based on a user's input, and generates a robust 2D map from the obtained 2D map via a post-processing modification process, and a 3D map generator that generates a 3D map from the robust 2D map.

According to embodiments, the post-processing modification process may include at least one of a modification process based on selective use of a filter and a modification process based on manipulation of a user interface (UI).

According to embodiments, the 3D map generator may generate mesh-based 3D map data from the robust 2D map, optimize the generated mesh-based 3D map data, and generate the 3D map based on the optimized mesh-based 3D map data.

According to embodiments, the 3D map generator may generate the 3D map from the robust 2D map using a filter.

According to embodiments, the system may further include a controller that determines whether to execute the post-processing modification process based on a degree of match between the 3D map generated by the 3D map generator and an actual map.

According to embodiments, the controller may simulate a movement of a moving object using the generated 3D map, and determine whether to modify the 3D map based on data obtained from the movement of the moving object.

According to embodiments, the controller may reflect actual environment data obtained based on the movement of the moving object into the 3D map generated by the 3D map generator.

According to the embodiments, the present disclosure may provide the system and the method for generating the three-dimensional (3D) map that may generate the 3D map using the design drawing or the robot data.

In addition, the present disclosure may provide the system and the method for generating the 3D map that may construct the 3D environment based on the generated 3D map and perform the simulation.

Effects obtainable from the present disclosure are not limited to the effects mentioned above, and other effects not mentioned will be clearly understood by those skilled in the art from the description below.

### BRIEF DESCRIPTION OF THE DRAWINGS

FIG. 1 shows a block diagram of a three-dimensional (3D) map generation system according to embodiments.

FIG. 2 shows a flowchart of a 3D map generation method according to embodiments.

FIG. 3 shows a flowchart that details a step of generating a 3D map in a 3D map generation method according to embodiments.

FIG. 4 shows a flowchart of generating a 3D map by a 3D map generation system and a 3D map generation method according to embodiments.

FIG. 5 shows an example of a post-processing modification process of a 3D map generation system and a 3D map generation method according to embodiments.

FIGS. 6 and 7 show a 3D map generation principle of a 3D map generation system and a 3D map generation method according to embodiments.

FIG. 8 shows an example of a 3D map generated by a 3D map generation system and a 3D map generation method according to embodiments.

FIG. 9 shows a flowchart specifying a 3D map generation method according to embodiments.

### DETAILED DESCRIPTION

Preferred embodiments of embodiments will be described in detail, and examples of which will be illustrated in the accompanying drawings. The detailed description below with reference to the accompanying drawings is intended to describe the preferred embodiments of the embodiments rather than to illustrate only embodiments that may be implemented according to the embodiments. The detailed description below includes details to provide a thorough understanding of the embodiments. However, it will be apparent to one skilled in the art that the embodiments may be practiced without such details.

Most of terms used in the embodiments are generally chosen from those widely used in the art, but some terms are arbitrarily chosen by the applicant and meanings thereof are described in detail in the following description as necessary. Therefore, the embodiments should be understood based on the intended meanings of the terms, not on the mere names or meanings of the terms.

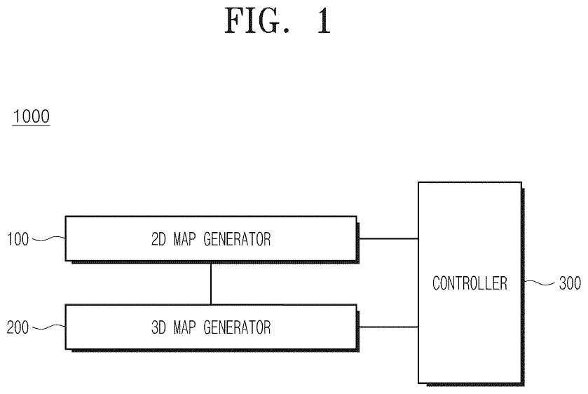

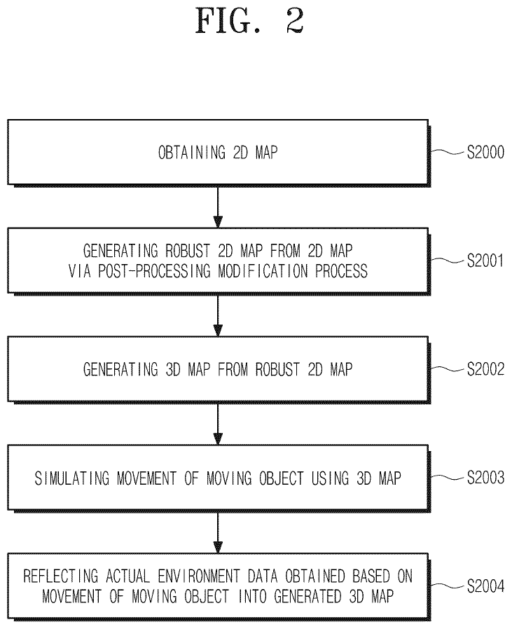

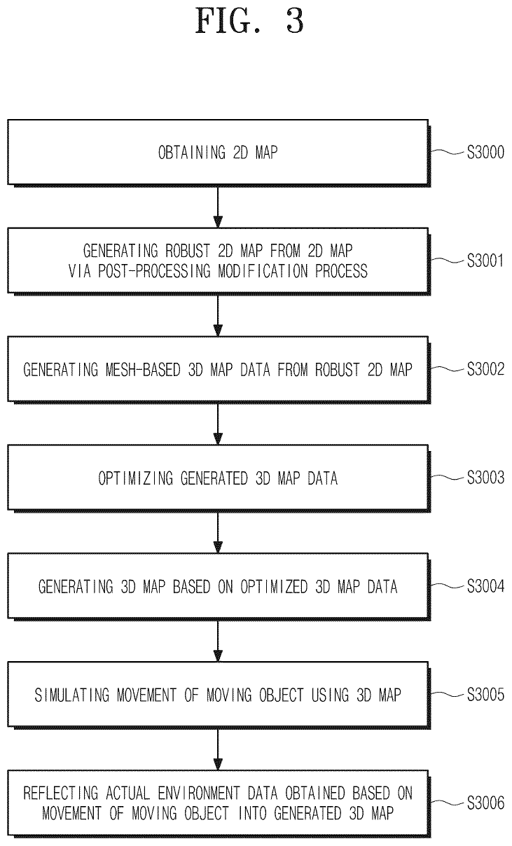

FIG. 1 shows a block diagram of a three-dimensional (3D) map generation system according to embodiments. FIG. 2 shows a flowchart of a 3D map generation method according to embodiments. FIG. 3 shows a flowchart that details a step of generating a 3D map in a 3D map generation method according to embodiments.

FIGS. 2 and 3 show a method for generating, by a 3D map generation system 1000 in FIG. 1, a 3D map based on a two-dimensional (2D) map generator 100, a 3D map generator 200, a controller 300, and the like in FIG. 1.

FIG. 3 shows a flowchart that details a step (S2002) of generating a 3D map illustrated in FIG. 2.

Referring to FIG. 1, the 3D map generation system 1000 according to embodiments may include the 2D map generator 100, the 3D map generator 200, and the controller 300.

The 2D map generator 100 may obtain a 2D map of a space by utilizing one of a floor plan or robot data based on a user's input, and may obtain a robust 2D map via a post-processing modification process from the obtained 2D map. In other words, the 2D map generator 100 may obtain the 2D map of the actual space, and may additionally generate the robust 2D map that is complementary to the obtained 2D map via the post-processing modification process.

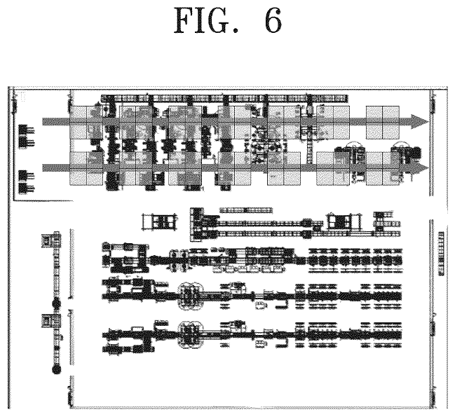

The 3D map generator 200 may generate a 3D map from the robust 2D map generated by the 2D map generator 100. A principle by which the 3D map generator 200 generates the 3D map from the robust 2D map will be described in detail in FIGS. 6 to 8.

The controller 300 may determine whether to execute the post-processing modification process based on a degree of match between the 3D map generated by the 3D map generator 200 and the actual map. That is, when determining that the generated 3D map does not match the actual map, the controller 300 may control the 2D map generator 100 to generate a new robust 2D map via the post-processing modification process of the generated robust 2D map again.

In addition, the controller 300 may simulate a movement of a moving object using the generated 3D map and determine whether to modify the 3D map based on data obtained based on the movement of the moving object. In this regard, the moving object may include a robot or the like. In addition, the controller 300 may update the generated 3D map such that actual environment data obtained based on the movement of the moving object is reflected into the 3D map generated by the 3D map generator 200.

Referring to FIG. 2, the 3D map generation method according to embodiments may include a step (S2000) of obtaining the 2D map of the space by utilizing one of the floor plan or the robot data based on the user's input, a step (S2001) of generating the robust 2D map from the 2D map via the post-processing modification process, the step (S2002) of generating the 3D map from the robust 2D map, a step (S2003) of simulating the movement of the moving object using the generated 3D map, and a step (S2004) of reflecting the actual environment data obtained based on the movement of the moving object into the generated 3D map.

Steps S2000 and S2001 may be performed by the 2D map generator 100 of the 3D map generation system 1000. Step S2002 may be performed by the 3D map generator 200 of the 3D map generation system 1000. Steps S2003 and S2004 may be performed by the controller 300 of the 3D map generation system 1000.

In particular, step S2003 may include determining a movement path of the moving object via the simulation, obtaining movement data of the moving object based on the determined movement path of the moving object, and determining whether to modify the 3D map based on the obtained data.

Referring to FIG. 3 together, the step (S2002) of generating the 3D map from the robust 2D map may include a step (S3002) of generating mesh-based 3D map data from the robust 2D map, a step (S3003) of optimizing the generated mesh-based 3D map data, and a step (S3004) of generating the 3D map based on the optimized mesh-based 3D map data.

Steps S3000, S3001, S3005, and S3006 illustrated in FIG. 3 may correspond to steps S2000, S2001, S2003, and S2004 illustrated in FIG. 2, respectively.

The step (S2002) of generating the 3D map from the robust 2D map will be described in detail in FIGS. 6 to 8.

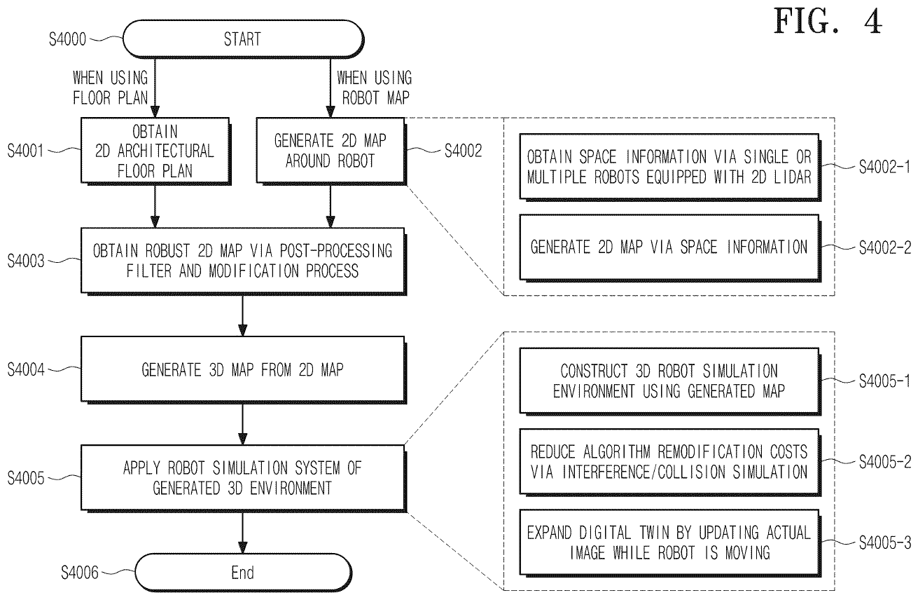

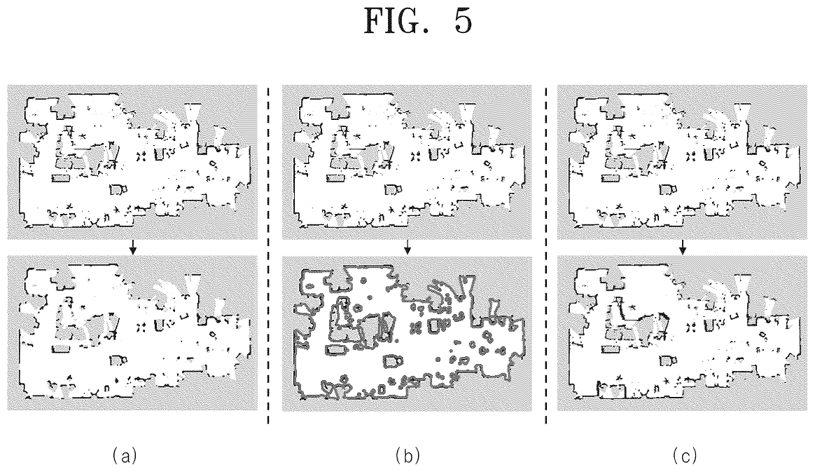

FIG. 4 shows a flowchart of generating a 3D map by a 3D map generation system and a 3D map generation method according to embodiments. FIG. 5 shows an example of a post-processing modification process of a 3D map generation system and a 3D map generation method according to embodiments.

FIG. 4 shows in detail a method for generating a 3D map by the 3D map generation system 1000 in FIG. 1 or the 3D map generation method in FIGS. 2 to 3.

Referring to FIG. 4, the 3D map generation system/method according to embodiments may start a 3D map generation logic when an input for start of 3D map generation is received from the user (S4000).

The 3D map generation system/method first obtains the 2D map (the floor plan) of the real space. In this regard, the 2D architectural floor plan may be obtained (S4001) or the 2D map may be obtained based on the robot data obtained using the robot (S4002). In this regard, whether to obtain the floor plan as the 2D map or to obtain the 2D map generated based on the robot data may be determined based on a user's input.

Steps S4001 and S4002 may be performed by the 2D map generator 100 of the 3D map generation system 1000 or may correspond to steps S2000 and S3000 of generating the 2D map in the 3D map generation method.

More specifically, in step S4002, the robot equipped with a sensor may first obtain information on a space (S4002-1), and may generate the 2D map via the obtained space information (which may correspond to the robot data) (S4002-2). In this regard, the sensor may be a lidar sensor or the like that may measure two-dimensional information or the like.

Therefore, the 3D map generation system/method according to embodiments may obtain the 2D map based on the floor plan or the robot data depending on user's selection as the 2D map.

The robust 2D map may be generated via the post-processing modification process of the 2D map obtained in step S4001 or step S4002 (S4003). That is, step S4003 may generate the 2D map (hereinafter, the ‘robust 2D map’) that is more suitable for the actual space via the additional modification process on the 2D map obtained/generated in step S4001 or step S4002.

Step S4003 may be performed by the 2D map generator 100 of the 3D map generation system 1000 or may correspond to steps S2001 and S3001 of generating the robust 2D map in the 3D map generation method.

The example of the post-processing modification process is illustrated in FIG. 5. The post-processing modification process may include a modification process based on selective use of a filter or a modification process based on manipulation of a user interface (UI).

Referring to FIG. 5 together, (a) in FIG. 5 shows a robust 2D map generated via a filter, and (b) and (c) in FIG. 5 show robust 2D maps generated via a modification process based on manipulation of a UI.

In particular, (b) in FIG. 5 shows a process of searching for an outline within the 2D map generated during the manipulation of the UI and modifying a wall based on the searched outline. More specifically, the user may select the outline of the generated 2D map and modify the walls at once, so-called collective modification or collective deletion. For example, as shown in (b) in FIG. 5, the user may perform the collective modification or the collective deletion at once within three groups of walls made of green, walls made of red, and walls made of blue.

Further, (c) in FIG. 5 shows a process of modifying, by the user, an outer wall using a mouse drag on the 2D map generated during the manipulation of the UI. More specifically, the user may finely create or delete the wall in the generated 2D map by clicking or dragging with the mouse.

Accordingly, the user may collectively delete or modify the outer walls or the like of the generated 2D map or may finely and partially delete or modify them depending on a situation.

The robust 2D map may be generated in step S4003, and the 3D map may be generated from the generated robust 2D map (S4004). The principle of generating the 3D map from the robust 2D map in step S4004 will be described in detail in FIGS. 6 to 8.

Step S4004 may be performed by the 3D map generator 200 of the 3D map generation system 1000 or may correspond to steps S2002 and S3002 to S3004 of generating a robust 3D map in the 3D map generation method.

In addition, a 3D environment may be generated via the generated 3D map, and the robot may be simulated within the generated 3D environment (S4005).

Step S4005 may be performed by the controller 300 of the 3D map generation system 1000 or may correspond to step S2003 (or step S3005) and step S2004 (or step S3006) in the 3D map generation method.

More specifically, step S4005 may include constructing the 3D robot simulation environment using the generated 3D map (S4005-1), or may include obtaining information on the movement path of the moving object within the simulation, and sensing whether interference/collision simulation of the moving object occurs (S4005-2). In particular, in step S4005-2, a path algorithm of the moving object may be modified when the interference/collision of the moving object occurs, thereby reducing costs. Alternatively, for example, step S4005 may include obtaining an actual image of surroundings when the moving object is moving within the simulation and reflecting the obtained actual image into the generated 3D map to update the 3D map (S4005-3).

Therefore, the 3D map generation system/method according to embodiments may define a virtual 3D space using the generated 3D map, and sense whether there is the collision/interference when the moving object such as the robot moves within the defined virtual 3D space.

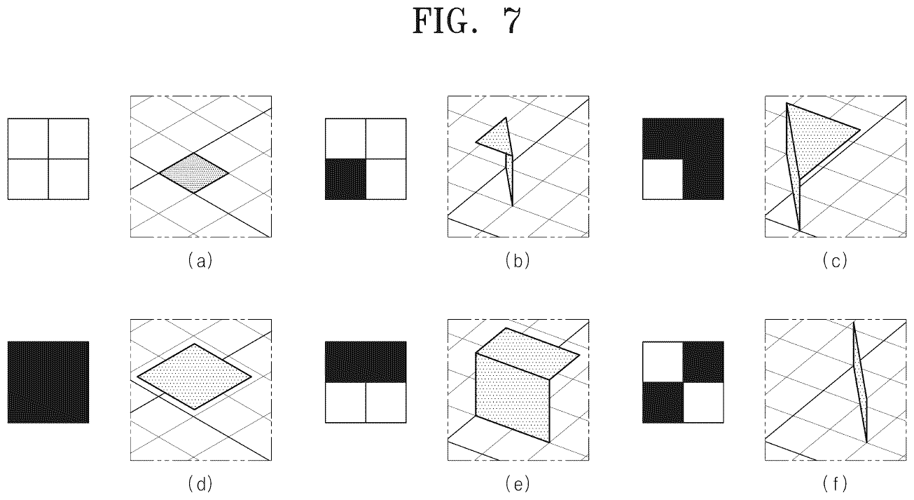

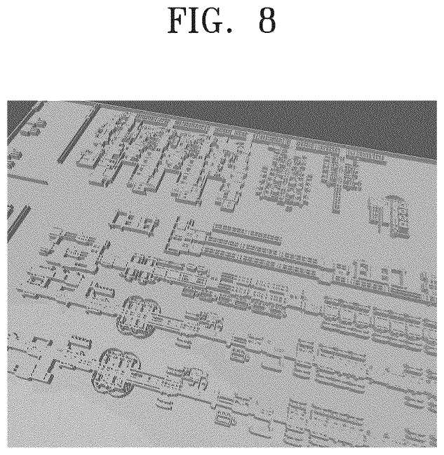

FIGS. 6 and 7 show a 3D map generation principle of a 3D map generation system and a 3D map generation method according to embodiments. FIG. 8 shows an example of a 3D map generated by a 3D map generation system and a 3D map generation method according to embodiments.

Referring to FIGS. 1 to 5 together, the 3D map generator 200 of the 3D map generation system according to embodiments or step S2002 in the 3D map generation method according to embodiments may generate the mesh-based 3D map data from the robust 2D map generated first (S3002). In this regard, the 3D map generator 200 or step S2002 may use a 2×2 square filter. That is, as illustrated in FIG. 6, the filter may scan the robust 2D map in a linear direction and generate a 3D plane based on indication within the filter that has performed the scanning.

FIG. 7 is a view showing a 3D plane generated based on indication within a filter that has performed scanning. As in (a) in FIG. 7, when (1,1), (1,2), (2,1), and (2,2) are all indicated in white within the filter that has performed the scanning, it may mean a plane in contact with a floor. Conversely, as in (d) in FIG. 7, when (1,1), (1,2), (2,1), and (2,2) are all indicated in black within the filter that has performed the scanning, it may mean a plane that is formed parallel to, but spaced apart from the floor.

Alternatively, as in (b) in FIG. 7, when only (2,1) is indicated in black and all the rest are indicated in white within the filter that has performed the scanning, it may mean a plane that is formed perpendicular to the floor but at an angle. Conversely, as in (c) in FIG. 7, when only (2,1) is indicated in white and all the rest are indicated in black within the filter that has performed the scanning, it may mean a plane that is formed perpendicular to the floor but at an angle, but is at an angle in an opposite direction to the angle of (b) in FIG. 7.

As in (e) in FIG. 7, when (1,1) and (1,2) are indicated in black and (2,1) and (2,2) are indicated in white within the filter that has performed the scanning, it may mean a plane that is perpendicular to the floor but is bent in one direction parallel to the floor. Alternatively, as in (f) in FIG. 7, when (1,1) and (2,2) are indicated in white and (1,2) and (2,1) are indicated in black within the filter that has performed the scanning, it may mean a plane that is perpendicular to the floor.

That is, the 3D plane may be generated based on the indication within the filter that has performed the scanning as in FIG. 7. Further, the generated mesh-based data may be optimized (S3003). In this regard, step S3003 may reduce a capacity by optimizing the 3D map data. Finally, the 3D map may be generated based on the optimized 3D map data (S3004).

FIG. 8 shows a 3D map generated by a 3D map generation system/method according to embodiments.

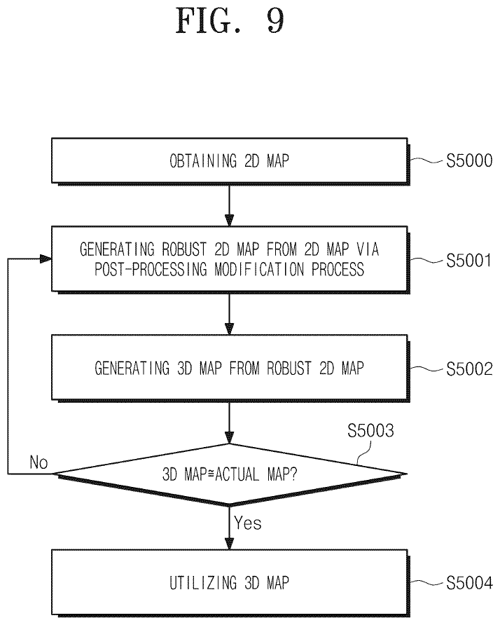

FIG. 9 shows a flowchart specifying a 3D map generation method according to embodiments.

FIG. 9 shows in detail a method for generating a 3D map by the 3D map generation system 1000 in FIG. 1 or the 3D map generation method in FIGS. 2 to 3.

Step S5000 illustrated in FIG. 9 may correspond to step S2000 illustrated in FIG. 2 or step S3000 illustrated in FIG. 3, step S5001 illustrated in FIG. 9 may correspond to step S2001 illustrated in FIG. 2 or step S3001 illustrated in FIG. 3, step S5002 illustrated in FIG. 9 may correspond to step S2002 illustrated in FIG. 2 or steps S3002 to S3004 illustrated in FIG. 3, and step S5004 illustrated in FIG. 9 may correspond to steps S2003 to S2004 illustrated in FIG. 2 or steps S3005 to S3006 illustrated in FIG. 3.

Referring to FIG. 9, the 3D map generation method according to embodiments may include determining whether the generated 3D map matches the actual map (S5003). Step S5003 may be performed by the controller 300 of the 3D map generation system 1000 in FIG. 1.

When it is determined in step S5003 that the 3D map matches the actual map to some extent (YES is selected in step S5003), the generated 3D map may be utilized (S5004). Alternatively, when it is determined in step S5003 that the 3D map does not match the actual map (NO is selected in step S5003), the generated 3D map may not be utilized and the new robust 2D map may be generated via the post-processing modification process again.

That is, the 3D map generation system/method according to embodiments may obtain the new robust 2D map when the generated 3D map does not match the actual map, and may generate the new 3D map via the new robust 2D map, thereby providing a feedback effect.

As described above, the detailed description of the preferred embodiments of the present disclosure is provided such that those skilled in the art may implement and practice the present disclosure. Although the description has been made above with reference to the preferred embodiments of the present disclosure, those skilled in the art will understand that the present disclosure may be modified and changed in various ways within a range that does not deviate from the scope of the present disclosure. For example, those skilled in the art may use the components described in the above-described embodiments in a way of combining them together.

Accordingly, the present disclosure is not intended to be limited to the embodiments described herein, but is intended to be accorded the widest scope consistent with the principles and novel features disclosed herein.

What is claimed is:

1. A method for generating a three-dimensional (3D) map, comprising:
obtaining a two-dimensional (2D) map of a space by utilizing one of a floor plan and robot data based on a user's input;
generating a robust 2D map from the 2D map via a post-processing modification process; and
generating the 3D map from the robust 2D map.

2. The method of claim 1, wherein the post-processing modification process includes at least one of a modification process based on selective use of a filter and a modification process based on manipulation of a user interface (UI).

3. The method of claim 1, wherein generating the 3D map includes:
generating mesh-based 3D map data from the robust 2D map;
optimizing the mesh-based 3D map data; and
generating the 3D map based on the optimized mesh-based 3D map data.

4. The method of claim 1, wherein generating the 3D map includes generating the 3D map from the robust 2D map using a filter.

5. The method of claim 1, further comprising determining whether to execute the post-processing modification process based on a degree of match between the generated 3D map and an actual map.

6. The method of claim 1, further comprising simulating a movement of a moving object using the generated 3D map,
wherein simulating the movement of the moving object includes determining whether to modify the 3D map based on data obtained from the movement of the moving object.

7. The method of claim 6, further comprising reflecting actual environment data obtained based on the movement of the moving object into the generated 3D map.

8. A system for generating a three-dimensional (3D) map, the system comprising:
a two-dimensional (2D) map generator configured to (1) obtain a 2D map of a space by utilizing one of a floor plan and robot data based on a user's input, and (2) generate a robust 2D map from the obtained 2D map via a post-processing modification process; and
a 3D map generator configured to generate a 3D map from the robust 2D map.

9. The system of claim 8, wherein the post-processing modification process includes at least one of a modification process based on selective use of a filter and a modification process based on manipulation of a user interface (UI).

10. The system of claim 8, wherein the 3D map generator is configured to generate mesh-based 3D map data from the robust 2D map, optimize the mesh-based 3D map data, and generate the 3D map based on the optimized mesh-based 3D map data.

11. The system of claim 8, wherein the 3D map generator is configured to generate the 3D map from the robust 2D map using a filter.

12. The system of claim 8, further comprising a controller configured to determine whether to execute the post-processing modification process based on a degree of match between the 3D map generated by the 3D map generator and an actual map.

13. The system of claim 12, wherein the controller is configured to simulate a movement of a moving object using the generated 3D map, and determine whether to modify the 3D map based on data obtained from the movement of the moving object.

14. The system of claim 13, wherein the controller is configured to reflect actual environment data obtained based on the movement of the moving object into the 3D map generated by the 3D map generator.
